(19) United States
(12) Patent Application Publication
(10) Pub. No.: US 2026/0271377 A1
(43) Pub. Date: Sep. 10, 2026

(54) SEMICONDUCTOR DEVICE

(71) Applicant: FUJI ELECTRIC CO., LTD., Kanagawa (JP)

(72) Inventor: Yasuyuki HOSHI, Matsumoto-city (JP)

(21) Appl. No.: 19/457,155

(22) Filed: Jan. 23, 2026

(30) Foreign Application Priority Data
Mar. 4, 2025 (JP) 2025-034051

(51) Int. Cl. H10D 84/00; H10D 8/00; H10D 12/00; H10D 62/10; H10D 62/60

(52) U.S. Cl. CPC H10D 84/161; H10D 8/422; H10D 12/415; H10D 12/481; H10D 62/107; H10D 62/126; H10D 62/60

(57) ABSTRACT

There is provided a semiconductor device including a transistor portion and a diode portion, wherein the transistor portion includes: an emitter region which includes a first emitter section of the first conductivity type and a second emitter section which is provided below the first emitter section and has a lower doping concentration than the first emitter section; a trench contact portion which extends from the front surface of the semiconductor substrate in a depth direction of the semiconductor substrate; and a trench contact sidewall region which is provided on a sidewall of the trench contact portion and provided between the trench contact portion and the second emitter section, and the diode portion includes a first conductivity type region of the first conductivity type which is provided above the drift region and in contact with the front surface electrode portion.

### CROSS-REFERENCE TO RELATED APPLICATIONS

The contents of the following patent application(s) are incorporated herein by reference:

NO. 2025-034051 filed in JP on Mar. 4, 2025.

### BACKGROUND

### TECHNICAL FIELD

The present invention relates to a semiconductor device.

### RELATED ART

Conventionally, in a semiconductor device such as an insulated gate bipolar transistor (IGBT), a technique of changing an arrangement of an emitter region or the like to adjust characteristics is known (see, for example, Patent Documents 1 to 3).

Patent Document 1: Japanese Patent Application Publication No. 2008-91491

Patent Document 2: Japanese Patent Application Publication No. H10-173170

Patent Document 3: Japanese Patent Application Publication No. H9-283755

### BRIEF DESCRIPTION OF THE DRAWINGS

FIG. 1 is a top view illustrating an example of a semiconductor device 100.

FIG. 2 is an example of an enlarged view of a region D in FIG. 1.

FIG. 3 is a view illustrating an example of a cross section taken along a line a-a of FIG. 2.

FIG. 4 is a graph indicating temporal change of collector current Ic and collector-emitter voltage VCE in reverse recovery.

FIG. 5 illustrates an example of a doping concentration distribution along a line h-h in FIG. 3.

FIG. 6 is another example of the enlarged view of the region D in FIG. 1.

FIG. 7 illustrates another example of the cross section taken along the line a-a in FIG. 2.

FIG. 8 illustrates another example of the cross section taken along the line a-a in FIG. 2.

FIG. 9 illustrates another example of the cross section taken along the line a-a in FIG. 2.

FIG. 10 illustrates another example of the cross section taken along the line a-a in FIG. 2.

FIG. 11 illustrates another example of the cross section taken along the line a-a in FIG. 2.

FIG. 12 illustrates another example of the cross section taken along the line a-a in FIG. 2.

FIG. 13 illustrates another example of the cross section taken along the line a-a in FIG. 2.

### DESCRIPTION OF EXEMPLARY EMBODIMENTS

The present invention will be described below by way of embodiments of the invention, but the embodiments below are not intended to limit the invention according to the claims. In addition, not all of combinations of features described in the embodiments are essential to a solution of the invention.

In the present specification, one side of a semiconductor substrate in a direction parallel to a depth direction is referred to as "upper" or "front" and another side is referred to as "lower" or "back". One surface of two principal surfaces of a substrate, a layer or another member is referred to as an upper surface or a front surface, and another surface is referred to as a lower surface or a back surface. "Upper", "lower", "front", and "back" directions are not limited to a direction of gravity, or a direction when a semiconductor device is implemented.

In the present specification, technical matters may be described using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. Note that a +Z axis direction and a -Z axis direction are directions opposite to each other. When the Z axis direction is described without describing its sign, it means a direction parallel to the +Z axis and the -Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as a depth direction. In addition, in the present specification, a direction parallel to the front surface and the back surface of the semiconductor substrate may be referred to as a horizontal direction, including the X axis and the Y axis.

A region from a center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

When a term such as “same” or “equal” is used in the present specification, it may encompass a case where an error due to manufacturing variations or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D} - N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the present specification, a description of a P+ type or an N+ type means a higher doping concentration than that of the P type or the N type, and a description of a P- type or an N- type means a lower doping concentration than that of the P type or the N type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration (atomic density) can be measured by secondary ion mass spectrometry (SIMS), for example. The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or /cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. In contrast, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (approximately 26.9 °C) may be used for a value at room temperature.

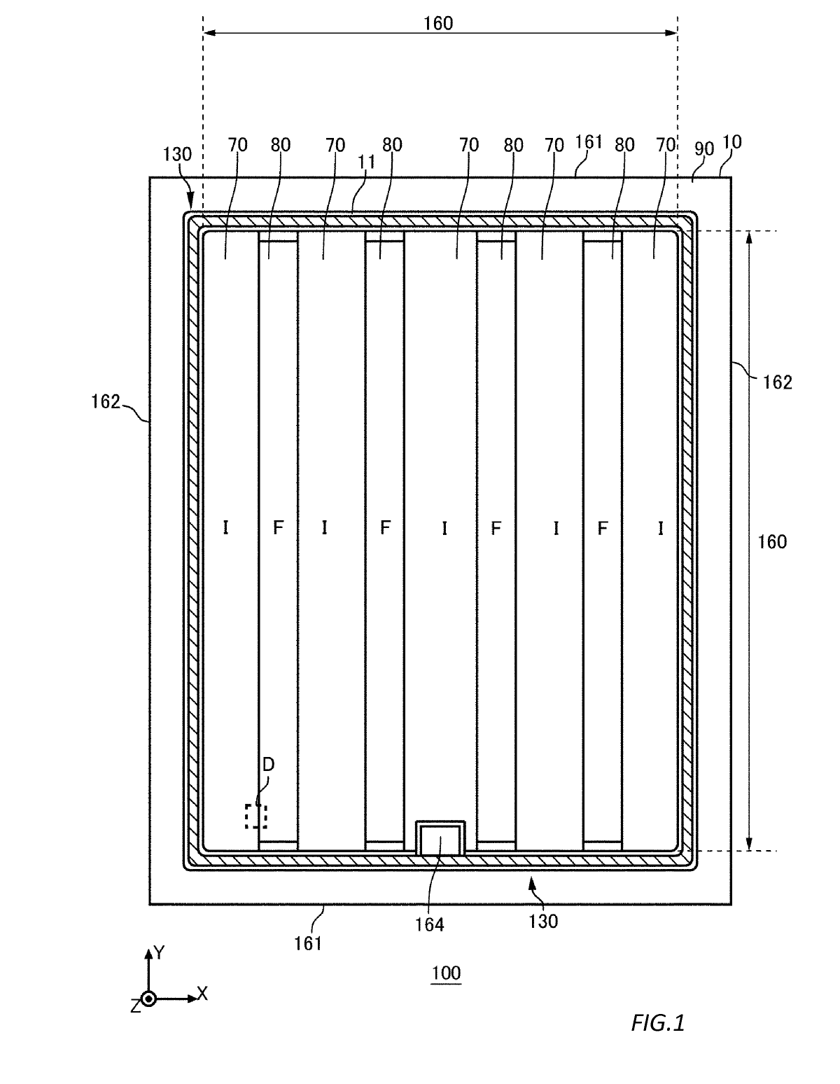

FIG. 1 is a top view illustrating an example of a semiconductor device 100. FIG. 1 illustrates a position of each member as being projected onto a front surface of a semiconductor substrate 10. FIG. 1 illustrates only some members of the semiconductor device 100, and some members are omitted.

The semiconductor device 100 includes the semiconductor substrate 10. The semiconductor substrate 10 is a substrate formed of a semiconductor material. Although the semiconductor substrate 10 is a silicon substrate, as an example, the material of the semiconductor substrate 10 is not limited to silicon. A material of the semiconductor substrate 10 may be silicon carbide (SiC), gallium nitride (GaN), or the like.

The semiconductor substrate 10 includes a first end side 161 and a second end side 162 in a top view. In the present specification, unless otherwise specified, a top view means a view from the front surface side of the semiconductor substrate 10. The semiconductor substrate 10 of the present example includes two sets of first end sides 161 facing each other in a top view. In addition, the semiconductor substrate 10 of the present example includes two sets of second end sides 162 facing each other in a top view. In FIG. 1, the first end side 161 is parallel to an X axis direction. The second end side 162 is parallel to a Y axis direction. In addition, the Z axis is perpendicular to the front surface of the semiconductor substrate 10. In addition, the first end side 161 is perpendicular to an extending direction or a longitudinal direction of a gate trench portion described below. The second end side 162 is parallel to the extending direction or the longitudinal direction of the gate trench portion described below.

The semiconductor substrate 10 is provided with an active portion 160. The active portion 160 is a region where a principal current flows in the depth direction between the front surface and the back surface of the semiconductor substrate 10 when the semiconductor device 100 operates. Although an emitter electrode, an interlayer dielectric film, and the like are provided above the active portion 160, they are omitted in FIG. 1.

In the active portion 160, there is provided a transistor portion 70 which includes a transistor element such as an IGBT, and a diode portion 80 which includes a diode element such as a freewheeling diode (FWD). The semiconductor device 100 of the present example is a Reverse Conducting IGBT (RC-IGBT).

In the example of FIG. 1, transistor portions 70 and diode portions 80 are alternately arranged along a predetermined arrangement direction (the X axis direction in the present example) of the front surface of the semiconductor substrate 10.

In FIG. 1, a region where each of the transistor portions 70 is arranged is indicated by a symbol "I", and a region where each of the diode portions 80 is arranged is indicated by a symbol "F". In the present specification, a direction perpendicular to the arrangement direction in a top view may be referred to as an extending direction (the Y axis direction in FIG. 1). Each of the transistor portions 70 and the diode portions 80 may have a longitudinal length in the extending direction. That is, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction, or a first direction, of each trench portion described below may be the same.

In FIG. 1, an end of the transistor portion 70 in the Y axis direction is positioned closer to a first end side 161 side than an end of the diode portion 80 in the Y axis direction. In addition, the width of the transistor portion 70 in the X axis direction is greater than the width of the diode portion 80 in the X axis direction.

The diode portion 80 includes a cathode region of the N+ type in a region in contact with the back surface of the semiconductor substrate 10. In the present specification, a region which is provided with a cathode region and extends in the Y axis direction is referred to as the diode portion 80.

The transistor portion 70 includes a collector region of the P+ type in a region in contact with the back surface of the semiconductor substrate 10. In the present specification, a region which is provided with a collector region and extends in the Y axis direction is referred to as the transistor portion 70. In the transistor portion 70, on the front surface side of the semiconductor substrate 10, an emitter region of the N type, a base region of the P type, and a gate trench portion including a gate conductive portion and a gate dielectric film are periodically arranged.

The semiconductor device 100 may have one or more pads above the semiconductor substrate 10. The semiconductor device 100 of the present example includes a gate pad 164. The semiconductor device 100 may have a pad such as an anode pad, a cathode pad, and a current detection pad. Each pad is arranged in a vicinity of the first end side 161. The vicinity of the first end side 161 refers to a region between the first end side 161 and the emitter electrode in a top view. When the semiconductor device 100 is implemented, each pad may be connected to an external circuit via wiring such as a wire.

A gate potential is applied to the gate pad 164. The gate pad 164 is electrically connected to a conductive portion of a gate trench portion of the active portion 160. The semiconductor device 100 includes a gate runner 130 that connects the gate pad 164 and the gate trench portion. In FIG. 1, the gate runner 130 is hatched with diagonal lines.

The gate runner 130 is arranged between the active portion 160 and the first end side 161 or the second end side 162 in a top view. The gate runner 130 of the present example surrounds the active portion 160 in a top view. A region surrounded by the gate runner 130 in a top view may be the active portion 160. In addition, the gate runner 130 is connected to the gate pad 164. The gate runner 130 is arranged above the semiconductor substrate 10. The gate runner 130 may be metal wiring including aluminum or the like, or may be made of polysilicon. The gate runner 130 may be provided separately from the emitter electrode.

A P type outer circumferential well region 11 overlaps with the gate runner 130. That is, similarly to the gate runner 130, the P type outer circumferential well region 11 surrounds the active portion 160 in a top view. The P type outer circumferential well region 11 extends with a predetermined width also in a range not overlapping the gate runner 130. The P type outer circumferential well region 11 is a region of a second conductivity type. The P type outer circumferential well region 11 of the present example is of the P+ type.

The semiconductor device 100 may include a temperature sensing portion (not shown) which is a PN junction diode formed of polysilicon or the like, and a current detection portion (not shown) which simulates an operation of the transistor portion 70 provided in the active portion 160. The temperature sensing portion may be connected to the anode pad and the cathode pad via wiring. When the temperature sensing portion is provided, it is preferably provided at a center of the semiconductor substrate 10 in the X axis direction and the Y axis direction.

The semiconductor device 100 of the present example includes an edge termination structure portion 90 between the active portion 160 and the first end side 161 or the second end side 162 in a top view of the semiconductor substrate 10. The edge termination structure portion 90 of the present example is arranged between the outer circumferential gate runner 130 and the first end side 161 or the second end side 162. The edge termination structure portion 90 alleviates electric field strength on the front surface side of the semiconductor substrate 10. The edge termination structure portion 90 may include at least one of a guard ring, a field plate, or a RESURF which are annularly provided to surround the active portion 160.

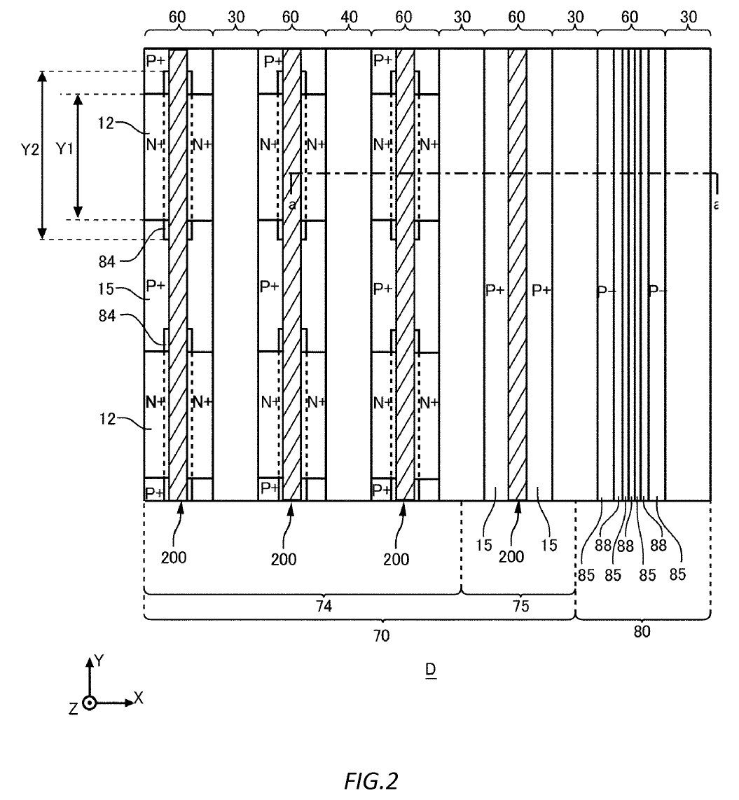

FIG. 2 is an example of an enlarged view of a region D in FIG. 1. The region D includes the transistor portion 70 and the diode portion 80 in the active portion 160 illustrated in FIG. 1. FIG. 2 illustrates a structure of the front surface of the semiconductor substrate 10 in the region D. Although an interlayer dielectric film 38 and an emitter electrode 52 are provided above the front surface of the semiconductor substrate 10, they are omitted in FIG. 2. The transistor portion 70 of the present example includes a main region 74 and a boundary region 75 which is provided in closer proximity to the diode portion 80 than the main region 74. A width of the boundary region 75 in the X axis direction may be 30 μm or more and 50 μm or less.

In the region D, the semiconductor device 100 includes a plurality of trench portions, a plurality of emitter regions 12, a plurality of contact regions 15, a plurality of trench contact sidewall regions 84, a plurality of second conductivity type regions 85, and a plurality of trench contact portions 200. The plurality of trench portions include one or more gate trench portions 40 and one or more dummy trench portions 30. In the present specification, each gate trench portion 40 and each dummy trench portion 30 may be referred to as a trench portion. When the term “trench portion” is simply mentioned in the present specification, the trench portion may be either the gate trench portion 40 or the dummy trench portion 30.

The gate trench portion 40 has its longitudinal length in the first direction on the front surface of the semiconductor substrate 10. The gate trench portion 40 of the present example extends in the Y axis direction, which is the first direction. The gate trench portion 40 is provided from the front surface of the semiconductor substrate 10 to an inside of the semiconductor substrate 10. A gate conductive portion formed of a conductive material such as polysilicon is arranged inside the gate trench portion 40. The gate conductive portion is electrically connected to the gate runner 130 (see FIG. 1), and a predetermined gate voltage is applied thereto.

A plurality of trench portions are arranged with a predetermined spacing in a second direction intersecting with the first direction. The second direction in the present example is the X axis direction orthogonal to the first direction (Y axis direction). In the present example, a trench portion adjacent to the gate trench portion 40 in the X axis direction may be the dummy trench portion 30. As illustrated in FIG. 2, a trench portion adjacent to the dummy trench portion 30 in the X axis direction may be the gate trench portion 40 or the dummy trench portion 30. One or more dummy trench portions 30 may be arranged between two gate trench portions 40 in the X axis direction. Note that, in another example, the dummy trench portions 30 may not be provided, and the gate trench portions 40 may be arranged adjacent to each other in the X axis direction.

A region of the semiconductor substrate 10 sandwiched between two trench portions in the X axis direction is defined as a mesa portion 60. Each end of the mesa portion 60 in the X axis direction is a boundary section with each trench portion. A width of the mesa portion 60 in the X axis direction may be 3 μm or less. A width of the mesa portion 60 in the transistor portion 70 in the X axis direction may be the same as a width of the mesa portion 60 in the diode portion 80 in the X axis direction. A depth position of a lower end of the mesa portion 60 is to be the same as a depth position of a lower end of at least one of the trench portions on both sides.

The transistor portion 70 of the present example is periodically provided with one or more gate trench portions 40 and one or more dummy trench portions 30 along the X axis direction. The diode portion 80 of the present example is provided with a plurality of dummy trench portions 30 along the X axis direction.

Each emitter region 12 is a region of a first conductivity type, which is exposed on the front surface of the semiconductor substrate 10. As an example, the first conductivity type is the N type. The emitter region 12 is in contact with the gate trench portion 40. The emitter region 12 may be provided in each mesa portion 60 in contact with the gate trench portion 40, in the main region 74 of the transistor portion 70. In contrast, the emitter region 12 may not be provided in the boundary region 75 of the transistor portion 70 and the diode portion 80. The emitter region 12 of the present example includes a first emitter section 81, a second emitter section 82, and a third emitter section 83. The first emitter section 81, the second emitter section 82, and the third emitter section 83 are each described below.

Each emitter region 12 may have a strip shape having its longitudinal length in the Y axis direction, or may have a rectangular shape, in a top view of the semiconductor substrate 10. In a top view of the semiconductor substrate 10, a length of one emitter region 12 in the Y axis direction is defined as Y1. Since each emitter region 12 has its longitudinal length in the Y axis direction, a channel formed below the emitter region 12 can have an increased length in the Y axis direction, and a channel density can be improved. Each emitter region 12 of the present example is in contact with any one of trench portions provided on both sides of the mesa portion 60.

In the main region 74 of the present example, as illustrated in FIG. 2, the plurality of emitter regions 12 may be arranged separately from each other in the Y axis direction, in one mesa portion 60. A distance between two emitter regions 12 which are adjacent to each other in the Y axis direction may be smaller than the length Y1, or may be less than or equal to half, may be less than or equal to 1/4, or may be less than or equal to 1/10 of the length Y1. In another example, only one emitter region 12 may be arranged continuously in the Y axis direction, in one mesa portion 60 of the main region 74. In this case, the length Y1 of the emitter region 12 may be greater than or equal to half or greater than or equal to 3/4 of a length of the mesa portion 60 in the Y axis direction.

Each contact region 15 is a region of the second conductivity type exposed on the front surface of the semiconductor substrate 10 in the mesa portion 60 and connected to the emitter electrode. As an example, the second conductivity type is the P type. The contact region 15 of the present example is a region of the P+ type, which has a higher doping concentration than a base region 14 of the P- type provided in the semiconductor substrate 10. Since the contact region 15 has a higher doping concentration than that of the base region 14, contact resistance between the contact region 15 and the emitter electrode can be reduced.

In the main region 74 of the present example, as illustrated in FIG. 2, in one mesa portion 60, the contact region 15 may be provided in a region where the emitter region 12 and the trench contact sidewall region 84 are not provided. In contrast, in the boundary region 75 of the present example, as illustrated in FIG. 2, in one mesa portion 60, the contact region 15 may extend in the Y axis direction along the trench portions. In the semiconductor device 100 of the present example, since the boundary region 75 is provided between the main region 74 and the diode portion 80, hole injection from the main region 74 is suppressed when the diode portion 80 is brought into conduction. This can reduce reverse recovery current, and reduce reverse recovery loss and turn-on loss.

The transistor portion 70 of the present example includes a trench contact portion 200 provided in each mesa portion 60. The trench contact portion 200 is a recess formed from the front surface 21 of the semiconductor substrate 10 to the inside of the semiconductor substrate 10. The inside of the trench contact portion 200 is filled with the emitter electrode 52. In FIG. 2, the range of the trench contact portion 200 is hatched with diagonal lines.

The trench contact sidewall region 84 is provided on a sidewall of the trench contact portion 200. The trench contact sidewall region 84 of the present example is a region of the P+ type, which has a higher doping concentration than that of the base region 14. In the main region 74 of the present example, as illustrated in FIG. 2, in one mesa portion 60, the plurality of trench contact sidewall regions 84 may be arranged separately from each other in the Y axis direction.

In another example, the trench contact sidewall region 84 may be a trench contact sidewall dielectric film provided on the sidewall of the trench contact portion 200. The trench contact sidewall dielectric film may be an oxide film. In this case, at least part of a bottom portion of the trench contact portion 200 is covered with a region of the P+ type.

Each trench contact sidewall region 84 may have a strip shape having its longitudinal length in the Y axis direction, or may have a rectangular shape, in a top view of the semiconductor substrate 10. In the main region 74 of the present example, in a top view of the semiconductor substrate 10, the trench contact sidewall region 84 may be arranged to overlap with the emitter region 12. In FIG. 2, an end of the trench contact sidewall region 84 arranged below the emitter region 12 is illustrated with dashed lines. In a top view of the semiconductor substrate 10, when a length of one trench contact sidewall region 84 in the Y axis direction is defined as Y2, the length Y2 may be greater than the length Y1. Thus, a contact area between the trench contact sidewall region 84 and the emitter electrode can be enlarged.

The second conductivity type region 85 and a first conductivity type region 88 are provided on the front surface of the semiconductor substrate 10, in the mesa portion 60 of the diode portion 80. As an example, the first conductivity type region 88 is of the N- type, and the second conductivity type region 85 is of the P- type.

In each mesa portion 60 in the diode portion 80 of the present example, a plurality of second conductivity type regions 85 extend in the Y axis direction along the dummy trench portion 30. Some of the plurality of second conductivity type regions 85 are provided on a sidewall of the dummy trench portion 30. A doping concentration of the second conductivity type region 85 may be the same as a doping concentration of the base region 14. In this case, the second conductivity type region 85 and the base region 14 can be formed in a same process. In another example, the doping concentration of the second conductivity type region 85 may be higher than the doping concentration of the base region 14.

The first conductivity type region 88 of the present example is exposed on the front surface of the semiconductor substrate 10, in a region in the mesa portion 60 where the second conductivity type region 85 is not provided. As illustrated in FIG. 2, in a top view of the semiconductor substrate 10, the second conductivity type region 85 of the present example extends in the Y axis direction between the second conductivity type regions 85 provided at each end of the mesa portion 60 in the X axis direction. That is, the second conductivity type region 85 and the first conductivity type region 88 of the present example have a stripe structure in a top view of the semiconductor substrate 10. In the mesa portion 60 in the diode portion 80 of the present example, in a top view of the semiconductor substrate 10, the first conductivity type region 88 and the second conductivity type region 85 are arranged alternately in the X axis direction.

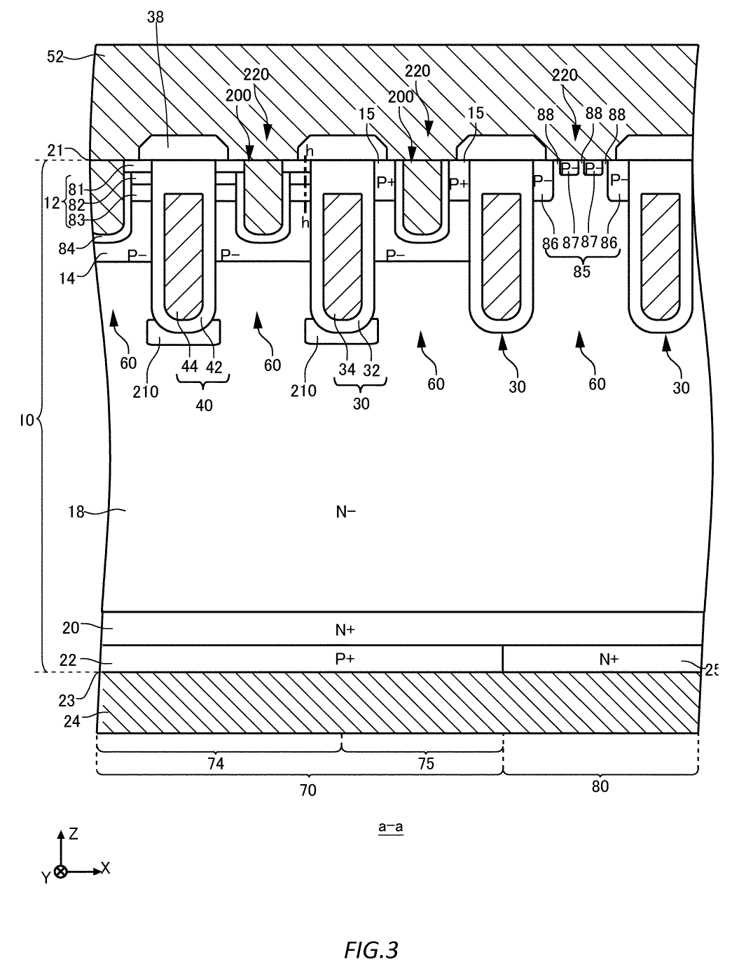

FIG. 3 illustrates an example of a cross section taken along a line a-a of FIG. 2. The cross section a-a is an XZ cross section passing through the emitter region 12, the contact region 15, the trench contact sidewall region 84, the second conductivity type region 85, and the first conductivity type region 88 on the front surface 21 of the semiconductor substrate 10. In the cross section, the semiconductor device 100 of the present example includes the semiconductor substrate 10, the interlayer dielectric film 38, the emitter electrode 52, and a collector electrode 24.

The emitter electrode 52 is provided above the front surface 21 of the semiconductor substrate 10. The emitter electrode 52 is an example of a front surface electrode portion. A part of the front surface 21 of the semiconductor substrate 10 is covered with the interlayer dielectric film 38. The emitter electrode 52 is in contact with at least a part of the front surface 21 of the semiconductor substrate 10 that is not covered with the interlayer dielectric film 38. The emitter electrode 52 of the present example is in contact with the contact region 15.

The emitter electrode 52 is formed of a material including metal. For example, at least a partial region of the emitter electrode 52 is formed of aluminum or an alloy mainly composed of aluminum, for example, a metal alloy such as AlSi, AlSiCu. The emitter electrode 52 may have a barrier metal formed of titanium, titanium nitride, or the like below a region formed of aluminum or the like. The barrier metal may be in contact with the semiconductor substrate 10. The emitter electrode 52 may have a metal plug formed tungsten or the like below the region formed of aluminum or the like. Each of the barrier metal and the metal plug is also an example of the front surface electrode portion.

The collector electrode 24 is provided on a back surface 23 of the semiconductor substrate 10. The collector electrode 24 may be formed of a metal material such as aluminum similarly to the emitter electrode 52, or may be formed by laminating a plurality of different metal materials. In the present specification, the direction from the emitter electrode 52 to the collector electrode 24 (the Z axis direction) is referred to as a depth direction.

The interlayer dielectric film 38 is provided on the front surface 21 of the semiconductor substrate 10. The interlayer dielectric film 38 is a film including at least one layer of a dielectric film such as silicate glass to which impurities such as boron or phosphorus are added, a thermal oxide film, or another dielectric film. The interlayer dielectric film 38 may cover each trench portion.

The interlayer dielectric film 38 of the present example includes a plurality of contact holes 220. Each contact hole 220 is provided between the emitter electrode 52 and the front surface 21 of the semiconductor substrate 10. The contact hole 220 of the present example is provided above each mesa portion 60. The emitter electrode 52 is electrically connected to the front surface 21 of the semiconductor substrate 10 through the contact holes 220. The contact holes 220 are filled with the emitter electrode 52. The emitter electrode 52 may have a plug formed of tungsten or the like in the contact hole 220. The plug may be formed by forming a barrier metal on a side in contact with the semiconductor substrate 10 in the contact hole 220 and embedding tungsten so as to be in contact with the barrier metal. A width of the contact hole 220 in the X axis direction may be 1 μm or more, and 2 μm or less.

The base region 14 of the P- type is provided in the mesa portion 60 of the transistor portion. The base region 14 is in contact with the gate trench portion 40. The base region 14 may be in contact with each of trench portions on both sides of the mesa portion 60. In the main region 74, at least part of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the N type to form a channel. The channel electrically connects the emitter region 12 and a drift region 18.

In the boundary region 75, the base region 14 is provided below the contact region 15. The base region 14 is in contact with the contact region 15. The base region 14 of the present example is a region of the P- type having a lower doping concentration than that of the contact region 15.

The semiconductor substrate 10 includes the drift region 18 of the N- type. The emitter region 12 has a higher doping concentration than the drift region 18. The drift region 18 is provided below the base region 14. An accumulation region of the N+ type having a higher doping concentration than the drift region 18 may be provided between the drift region 18 and the base region 14. Providing the accumulation region can produce an electron injection enhancement effect to decrease an ON voltage of the semiconductor device 100.

In the transistor portion 70, a collector region 22 of the P+ type is provided between the drift region 18 and the back surface 23 of the semiconductor substrate 10. A doping concentration of the collector region 22 is higher than the doping concentration of the base region 14. The collector region 22 may include an acceptor which is the same as or different from an acceptor of the base region 14. The acceptor of the collector region 22 is, for example, boron. The element serving as the acceptor is not limited to the example described above. The collector region 22 is exposed on the back surface 23 of the semiconductor substrate 10 and in contact with the collector electrode 24.

In the diode portion 80 of the present example, a cathode region 25 of the N+ type is provided between the drift region 18 and the back surface 23 of the semiconductor substrate 10. A doping concentration of the cathode region 25 is higher than a doping concentration of the drift region 18. In another example, the cathode region 25 may not be provided and the drift region 18 may be exposed on the back surface 23 of the semiconductor substrate 10 to be in contact with the collector electrode 24.

A buffer region 20 of the N+ type may be provided between the drift region 18, and the collector region 22 and the cathode region 25. The doping concentration in the buffer region 20 is higher than the doping concentration in the drift region 18. The buffer region 20 may have one or more concentration peaks having a doping concentration higher than that of the drift region 18. The doping concentration of the concentration peak refers to a doping concentration at the apex of the concentration peak. In addition, as the doping concentration of the drift region 18, an average value of doping concentrations in the region where the doping concentration distribution is substantially flat may be used.

The buffer region 20 may be formed by ion implantation of the dopant of the N type such as hydrogen (proton) or phosphorus. The buffer region 20 of the present example is formed by the ion implantation of hydrogen. The buffer region 20 may function as a field stopper layer which prevents a depletion layer expanding from a lower end of the base region 14 from reaching the collector region 22.

One or more gate trench portions 40 are provided at the front surface 21 of the semiconductor substrate 10. In the present example, a plurality of gate trench portions 40 are provided at the front surface 21 of the semiconductor substrate 10. In the present example, each gate trench portion 40 penetrates the base region 14 from the front surface 21 of the semiconductor substrate 10 and reaches the drift region 18. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

The gate trench portion 40 includes a groove-shaped gate trench provided on the front surface 21 of the semiconductor substrate 10, a gate dielectric film 42, and a gate conductive portion 44. The gate conductive portion 44 is formed of polysilicon which is a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 inside the gate trench. In other words, the gate dielectric film 42 insulates the gate conductive portion 44 from the semiconductor substrate 10.

The gate conductive portion 44 in the gate trench portion 40 may be provided longer than the base region 14 in the depth direction. The gate trench portion 40 in the cross section is covered with the interlayer dielectric film 38 on the front surface 21 of the semiconductor substrate 10. The gate conductive portion 44 is electrically connected to the gate runner 130 at a position other than the cross section illustrated in FIG. 3.

The dummy trench portion 30 has a structure similar to that of the gate trench portion 40. The dummy trench portion 30 in the present example includes a groove-shaped dummy trench, a dummy dielectric film 32, and a dummy conductive portion 34. Structures of the dummy trench, the dummy dielectric film 32, and the dummy conductive portion 34 are similar to those of the gate trench, the gate dielectric film 42, and the gate conductive portion 44. The dummy trench portion 30 in the cross section is covered with the interlayer dielectric film 38 on the front surface 21 of the semiconductor substrate 10. The dummy conductive portion 34 is electrically connected to the emitter electrode 52 at a position which is not on the cross section illustrated in FIG. 3.

The transistor portion 70 includes a trench bottom region 210 of the second conductivity type provided below the trench portion. The trench bottom region 210 of the present example is of the P- type. The trench bottom region 210 of the present example covers a bottom portion of the trench portion. In another example, the trench bottom region 210 may be spaced apart from the bottom portion of the trench portion. The trench bottom region 210 of the present example is surrounded by the drift region 18.

The trench bottom region 210 of the present example is provided in the main region 74 of the transistor portion 70. The trench bottom region 210 may not be provided in the boundary region 75. Each trench bottom region 210 of the present example is spaced apart from the trench bottom region 210 provided below an adjacent trench portion.

The trench bottom region 210 of the present example is provided below the gate trench portion 40. The trench bottom region 210 may or may not be provided below the dummy trench portion 30.

A width of the trench bottom region 210 in the X axis direction may be the same as or greater than a width of the trench portion in the X axis direction. The trench bottom region 210 may extend in the Y axis direction along the trench portion, or a plurality of trench bottom regions 210 may be provided separately from each other along one trench portion.

The trench bottom region 210 may be in contact with the P type outer circumferential well region 11 at its end in the Y axis direction. In this case, since the trench bottom region 210 is electrically connected to the emitter electrode 52, the hole injection from the transistor portion 70 to the diode portion 80 is suppressed, and the reverse recovery loss can be reduced.

Alternatively, the trench bottom region 210 may be a floating layer which is not electrically connected to a predefined potential such as the emitter electrode 52. In this case, the trench bottom region 210 can improve a turn-on characteristic by reducing dependency of dV/dt in the diode portion 80 on the gate resistance to allow for driving with a small gate resistance.

The transistor portion 70 of the present example includes the trench contact portion 200 below the contact hole 220. The trench contact portion 200 of the present example extends, in the mesa portion 60 of the transistor portion 70, from the front surface 21 of the semiconductor substrate 10 in the depth direction of the semiconductor substrate 10, and provided to a position deeper than an upper end of the base region 14. A width of the trench contact portion 200 in the X axis direction may be smaller than a width of the contact hole 220 in the X axis direction. The inside of the trench contact portion 200 is filled with the emitter electrode 52 similarly to the contact hole 220. The trench contact portion 200 may contain tungsten. The emitter electrode 52 and the semiconductor substrate 10 contacts each other on the sidewall and the bottom portion of the trench contact portion 200. This allows an increase in a contact area between the emitter electrode 52 and the semiconductor substrate 10.

In the present example, the sidewall of the trench contact portion 200 is in contact with the trench contact sidewall region 84. The bottom portion of the trench contact portion 200 may also be in contact with the trench contact sidewall region 84. A part of the sidewall of the trench contact portion 200 may be in contact with the first emitter section 81 described below, and a remaining region thereof may be covered with the trench contact sidewall region 84. The trench contact sidewall region 84 of the present example is a region of the P+ type, which has a higher doping concentration than that of the base region 14. Thus, a hole current flowing toward the front surface 21 side of the semiconductor substrate 10 can be extracted, so that latch-up can be suppressed.

Although the sidewall of the trench contact portion 200 is illustrated as being perpendicular to the front surface 21 of the semiconductor substrate 10 in FIG. 3, it may be inclined thereto. In addition, although the bottom portion of the trench contact portion 200 is illustrated in a downwardly bent shape, it may be flat. The sidewall and the bottom portion of the trench contact portion 200 are distinguished from each other merely for convenience. Portions in which outer surfaces of the trench contact portion 200 extend from the front surface 21 of the semiconductor substrate 10 in the depth direction may be referred to as sidewalls, and a portion which extends in a different direction from the sidewalls and connects the sidewalls with each other may be referred to as a bottom portion.

The trench contact portion 200 may not be provided in the mesa portion 60 of the diode portion 80. The diode portion 80 of the present example is in contact with the emitter electrode 52 via the contact hole 220 on the front surface 21 of the semiconductor substrate 10.

The emitter region 12 of the present example includes a first emitter section 81 of the N+ type and a second emitter section 82 of the N type. The emitter region 12 may further include a third emitter section 83 of the N+ type. The first emitter section 81 is in contact with the front surface 21 of the semiconductor substrate 10. The first emitter section 81 is a region of the N+ type having a higher doping concentration than that of the drift region 18. The first emitter section 81 of the present example is in contact with a sidewall of the gate trench portion 40. Furthermore, the first emitter section 81 of the present example is in contact with the sidewall of the trench contact portion 200. The first emitter section of the present example extends from the gate trench portion 40 to the trench contact portion 200 in the X axis direction.

The second emitter section 82 is provided below the first emitter section 81 to be in contact with the first emitter section 81. The second emitter section 82 is a region of the N type having a lower doping concentration than that of the first emitter section 81. The second emitter section 82 of the present example is in contact with the sidewall of the gate trench portion 40. The second emitter section 82 of the present example is not in contact with the sidewall of the trench contact portion 200 and is in contact with the trench contact sidewall region 84. That is, the trench contact sidewall region 84 of the present example is provided between the trench contact portion 200 and the second emitter section 82. Therefore, a width of the second emitter section 82 of the present example in the X axis direction is smaller than a width of the first emitter section 81 in the X axis direction.

The second emitter section 82 of the present example has a doping concentration lower than that of the first emitter section 81. This increases a resistance value of the second emitter section 82. In addition, a current flowing between the first emitter section 81 and the base region 14 passes through the second emitter section 82. Thus, the second emitter section 82 of the present example functions as a resistance portion, and can suppress a saturation current flowing through a MOS structure. In addition, providing the emitter region 12 having its longitudinal length in the Y axis direction increases a total emitter width in the Y axis direction and reduces the ON voltage. In this way, by providing the second emitter section 82 functioning as a resistance portion, it is possible to achieve both a low saturation current and a low ON voltage.

The third emitter section 83 is provided below the second emitter section 82 to be in contact with the second emitter section 82. The third emitter section 83 is a region of the N+ type having a higher doping concentration than that of the second emitter section 82. The third emitter section 83 may have a doping concentration lower than that of the first emitter section 81. The third emitter section 83 of the present example is in contact with the sidewall of the gate trench portion 40. Similar to the second emitter section 82, the third emitter section 83 of the present example is not in contact with the sidewall of the trench contact portion 200 and is in contact with the trench contact sidewall region 84. That is, the trench contact sidewall region 84 of the present example is provided between the trench contact portion 200 and the third emitter section 83. Therefore, in the present example, a width of the third emitter section 83 in the X axis direction is also smaller than the width of the first emitter section 81 in the X axis direction.

In the depth direction of the semiconductor substrate 10, an upper end of the gate conductive portion 44 of the gate trench portion 40 is arranged to face the third emitter section 83. The upper end of the gate conductive portion 44 may refer to an upper end on its sidewall which faces the mesa portion 60. The phrase “the upper end of the gate conductive portion 44 faces the third emitter section 83” means that in the Z axis direction, the upper end of the gate conductive portion 44 is arranged between an upper end position and a lower end position of the third emitter section 83. An upper end and a lower end of the third emitter section 83 may refer to an upper end and a lower end in a portion thereof which is in contact with the sidewall of the gate trench portion 40.

When the ON voltage is applied to the gate conductive portion 44, electrons are attracted to a region of the mesa portion 60 that faces the gate conductive portion 44, in a boundary section between the mesa portion 60 and the trench portion. When the second emitter section 82 and the gate conductive portion 44 are arranged to face each other, electrons are also attracted to a boundary section of the second emitter section 82. Since the second emitter section 82 has a low doping concentration, a resistance value at the boundary section may vary due to the attracted electrons. To address this variation, the third emitter section 83 is arranged to face the upper end of the gate conductive portion 44, whereby it is possible to suppress the variation in the resistance value at the boundary section of the second emitter section 82. In addition, since the third emitter section 83 has a high doping concentration, even when electrons are attracted to a boundary section of the third emitter section 83, the variation in the resistance value at the boundary section is extremely small.

The first emitter section 81 of the present example is in contact with the trench contact portion 200. This can decrease connection resistance between the emitter electrode 52 and the first emitter section 81. The first emitter section 81 may be in contact with an upper end of the trench contact sidewall region 84 on the sidewall of the trench contact portion 200.

The second emitter section 82 is not in contact with the trench contact portion 200. The trench contact sidewall region 84 may be provided between the second emitter section 82 and the trench contact portion 200. The second emitter section 82 of the present example is in contact with the trench contact sidewall region 84 provided on the sidewall of the trench contact portion 200. Such a configuration can prevent a current from flowing between the emitter electrode 52 and the second emitter section 82 through a path other than the first emitter section 81.

The third emitter section 83 is not in contact with the trench contact portion 200. The trench contact sidewall region 84 may be provided between the third emitter section 83 and the trench contact portion 200. The third emitter section 83 of the present example is in contact with the trench contact sidewall region 84 provided on the sidewall of the trench contact portion 200. Such a configuration can prevent a current having passed through a channel of the base region 14 from flowing to the emitter electrode 52 without passing through the second emitter section 82.

The diode portion 80 of the present example includes the second conductivity type region 85 of the second conductivity type and the first conductivity type region 88 of the first conductivity type which are provided above the drift region 18 and in contact with the emitter electrode 52. As an example, the first conductivity type region 88 is of the N- type and the second conductivity type region 85 is of the P- type. In the present example, the second conductivity type region 85 and the first conductivity type region 88 are provided on the front surface of the semiconductor substrate 10 in the mesa portion 60 of the diode portion 80.

The second conductivity type region 85 functions as an anode region of the diode portion 80. The second conductivity type region 85 of the present example includes a trench sidewall region 86 and a front surface region 87. The trench sidewall region 86 of the present example is provided on the sidewall of the dummy trench portion 30. The trench sidewall region 86 of the present example extends from the front surface 21 of the semiconductor substrate 10 along the sidewall of the dummy trench portion 30, in the depth direction of the semiconductor substrate 10. The front surface region 87 of the present example is provided, on the front surface 21 of the semiconductor substrate 10, between trench sidewall regions 86 provided at each end of the mesa portion 60 in the X axis direction. A width of the trench sidewall region 86 in the X axis direction may be 0.2 μm or more and 3 μm or less. A width of the front surface region 87 in the X axis direction may be 0.1 μm or more and 3 μm or less. Although in FIG. 3, two rows of front surface regions 87 are provided between the trench sidewall regions 86 in the mesa portion 60 of the diode portion 80, their arrangement is not limited thereto, and more than two rows of the front surface regions 87 may be provided.

In the present example, a lower end of the trench sidewall region 86 is positioned deeper than a lower end of the front surface region 87. In the present example, a depth of the lower end of the trench sidewall region 86 is greater than or equal to a depth of a lower end of the emitter region 12. In the depth direction of the semiconductor substrate 10, a thickness of the trench sidewall region 86 may be 0.3 μm or more and 3 μm or less. The trench sidewall region 86 functions as a guard ring which alleviates an electric field in switching. In contrast, the lower end of the front surface region 87 is at a shallower depth than the lower end of the emitter region 12. The lower end of the front surface region 87 may be at a shallower depth than a lower end of the second emitter section 82. In the depth direction of the semiconductor substrate 10, a thickness of the front surface region 87 may be 0.2 μm or more and 2 μm or less. A depth position of the lower end of the front surface region 87 can be adjusted according to time and temperature of thermal diffusion. Providing the lower end of the front surface region 87 at a shallow depth prevents a spacing between the front surface region 87 and the adjacent trench sidewall region 86 or front surface region 87 from being narrowed due to the thermal diffusion and secures a region in which the first conductivity type region 88 is provided.

The doping concentration of the second conductivity type region 85 may be 1E10¹³ cm⁻³ or more. The doping concentration of the second conductivity type region 85 may be the same as the doping concentration of the base region 14. In this case, the second conductivity type region 85 and the base region 14 can be formed in a same process. In another example, the doping concentration of the second conductivity type region 85 may be higher than the doping concentration of the base region 14.

The first conductivity type region 88 of the present example is exposed on the front surface 21 of the semiconductor substrate 10, in a region where the second conductivity type region 85 in the mesa portion 60 of the diode portion 80 is not provided. In other words, the first conductivity type region 88 of the present example is provided in a region from which some of the second conductivity type regions 85 have been removed, in the mesa portion 60 of the diode portion 80. A width of the first conductivity type region 88 in the X axis direction may be 0.2 μm or more and 1 μm or less. The first conductivity type region 88 of the present example is the drift region 18. In another example, the first conductivity type region 88 may be set as a region having a doping concentration such that it makes a Schottky contact with the emitter electrode 52.

In this way, in the mesa portion 60 of the diode portion 80 of the present example, the second conductivity type region 85 is not entirely exposed on the front surface 21 of the semiconductor substrate 10, but the first conductivity type region 88 is partially exposed thereon. Such a structure can suppress the hole injection and reduce the reverse recovery loss.

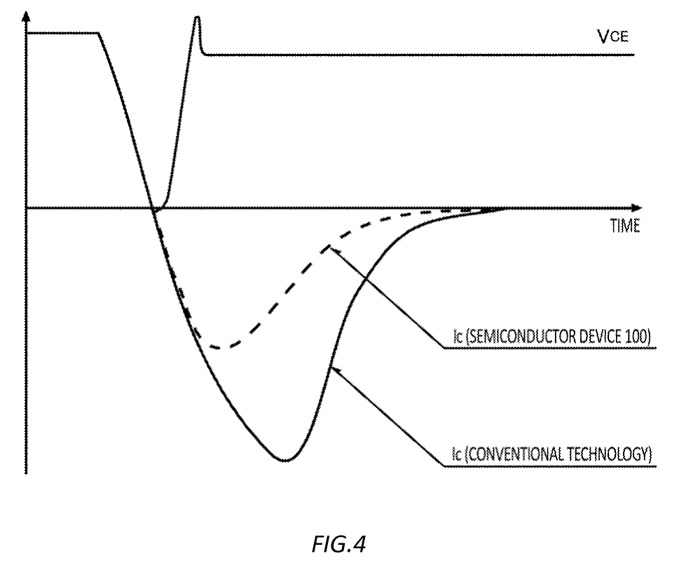

FIG. 4 is a graph indicating temporal change of collector current Ic and collector-emitter voltage VCE in reverse recovery. Among collector currents Ic indicated in the graph of FIG. 4, a solid line indicates collector current Ic of a semiconductor device according to conventional technology, and a dashed line indicates collector current Ic in the semiconductor device 100 of the present example. The semiconductor device according to the conventional technology is not provided with the first conductivity type region 88. Behavior of the collector current Ic in the semiconductor device 100 of the present example overlaps that of the collector current Ic of the semiconductor device according to the conventional technology indicated by the solid line, during the time which is outside a range indicated by the dashed line.

When the transistor portion is turned off and the diode portion is brought into conduction, electron current flows from the cathode region to the base region operating as an anode layer to generate the reverse recovery current. When the electron current reaches the base region, conductivity modulation occurs and hole current flows from the anode layer. Furthermore, the electron current from the cathode region also diffuses to the base region of the transistor portion.

Due to the electron current diffused toward the transistor portion, since the hole injection from the contact region having a higher doping concentration than that of the base region is promoted, and a hole density in the semiconductor substrate increases, the time required for holes to disappear after turning off the diode portion becomes longer. Thus, since reverse recovery peak current increases and the time until current becomes zero gets longer, heat generation increases and the reverse recovery loss increases.

In contrast, in the semiconductor device 100 of the present example, since some of the second conductivity type regions 85 functioning as anode regions are removed to provide the first conductivity type region 88, the hole injection when the diode portion 80 is brought into conduction can be suppressed. Thus, as illustrated in FIG. 4, the reverse recovery peak current can be suppressed and the reverse recovery loss can be reduced.

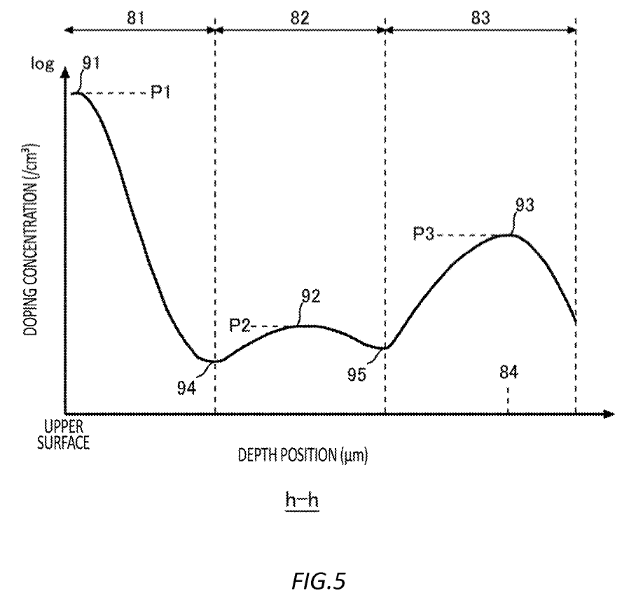

FIG. 5 illustrates an example of a doping concentration distribution along a line h-h in FIG. 3. The line h-h is a line parallel to the Z axis, which passes through the first emitter section 81, the second emitter section 82, and the third emitter section 83.

The first emitter section 81 of the present example has a peak portion 91 of the doping concentration distribution in the depth direction of the semiconductor substrate 10. A peak of the doping concentration distribution is a mountain-shaped portion exhibiting a local maximum value at its apex. A doping concentration at the apex of the peak portion is defined as a doping concentration of the peak portion. The doping concentration of the peak portion 91 is defined as P1. Note that, in the first emitter section 81, its doping concentration may increase continuously from a boundary with the second emitter section 82 to the front surface 21 of the semiconductor substrate 10. In this case, the doping concentration of the first emitter section 81 on the front surface 21 of the semiconductor substrate 10 is to be P1.

The second emitter section 82 of the present example has a peak portion 92 of the doping concentration distribution in the depth direction of the semiconductor substrate 10. A doping concentration of the peak portion 92 is defined as P2. Between the first emitter section 81 and the second emitter section 82, a valley portion 94 where the doping concentration exhibits a local minimum value is defined as a boundary between the first emitter section 81 and the second emitter section 82. The second emitter section 82 may include, between the valley portion 94 and the peak portion 92, a flat section where the doping concentration distribution in the depth direction of the semiconductor substrate 10 is flat.

The third emitter section 83 of the present example has a peak portion 93 of the doping concentration distribution in the depth direction of the semiconductor substrate 10. A doping concentration of the peak portion 93 is defined as P3. Between the second emitter section 82 and the third emitter section 83, a valley portion 95 where the doping concentration exhibits a local minimum value is defined as a boundary between the second emitter section 82 and the third emitter section 83.

As described above, the doping concentration P2 at the peak portion 92 of the second emitter section 82 is lower than the doping concentration P1 at the peak portion 91 of the first emitter section 81. The doping concentration P2 may be 1/100 times or less, or 1/1000 times or less of the doping concentration P1. The doping concentration P2 may be 10 times or less, or five times or less of the doping concentration at the valley portion 94. The doping concentration P2 is higher than the doping concentration of the drift region 18. The doping concentration P2 may be 100 times or less, 10 times or less, or five times or less of the doping concentration of the drift region 18. Adjusting the doping concentration P2 can adjust the resistance value of the second emitter section 82 functioning as a resistance portion.

A length of the second emitter section 82 in the depth direction of the semiconductor substrate 10 may be 2 μm or less. The length may be 1.5 μm or less, or may be 1 μm or less. The length may be 0.1 μm or more, or may be 0.5 μm or more. A length of an entire emitter region 12 in the depth direction of the semiconductor substrate 10 may be 3 μm or less.

The emitter region 12 of the present example can be formed by implanting a dopant ion of the N type at each position of the peak portion 91, the peak portion 92, and the peak portion 93. The length of the second emitter section 82 in the depth direction of the semiconductor substrate 10 can be adjusted by adjusting depth positions where the peak portion 91 and the peak portion 93 are formed. Adjusting the length of the second emitter section 82 can adjust the resistance value of the second emitter section 82 functioning as a resistance portion.

As described above, the doping concentration P3 at the peak portion 93 of the third emitter section 83 is higher than the doping concentration P2 at the peak portion 92 of the second emitter section 82. The doping concentration P3 may be 10 times or more, 50 times or more, or 100 times or more of the doping concentration P2. The doping concentration P3 at the peak portion 93 of the third emitter section 83 may be less than or equal to the doping concentration P1 at the peak portion 91 of the first emitter section 81. The doping concentration P3 may be 1/2 times or less, 1/5 times or less, or 1/10 times or less of the doping concentration P1.

As described in FIG. 3, a depth position of the upper end of the gate conductive portion 44 is within a depth range over which the third emitter section 83 is provided. The upper end of the gate conductive portion 44 may be provided within a range of a full width at half maximum of the peak portion 93. The range of the full width at half maximum of the peak portion 93 is a range in which a doping concentration in the peak portion 93 is greater than or equal to one half of P3.

A length of the third emitter section 83 in the depth direction of the semiconductor substrate 10 may be 0.4 μm or more. Thus, even when there are variations in the depth position of the upper end of the gate conductive portion 44 due to manufacturing variations or the like, the upper end of the gate conductive portion 44 can be arranged at a position facing the third emitter section 83. The length of the third emitter section 83 in the depth direction of the semiconductor substrate 10 may be 1 μm or less. The third emitter section 83 may be provided in a range in the depth direction of the semiconductor substrate 10 which can absorb variations in the depth position of the upper end of the gate conductive portion 44. When the length of the third emitter section 83 in the depth direction of the semiconductor substrate 10 is to be 1 μm or less, an entire length of the emitter region 12 in the depth direction of the semiconductor substrate 10 can be decreased.

In this way, since the emitter region 12 of the present example can include the second emitter section 82 functioning as a resistance portion to suppress peak current when turned on, a width of the boundary region 75 in the X axis direction, which does not operate as a MOS, can be reduced. A width of the boundary region 75 of the present example in the X axis direction is 30 μm or more and 50 μm or less. Note that, when the width of the boundary region 75 in the X axis direction becomes smaller, the hole injection from the main region 74 of the transistor portion 70 increases when the diode portion 80 is brought into conduction. Therefore, in the semiconductor device 100 of the present example, since the first conductivity type region 88 is in contact with the emitter electrode 52 to suppress the hole injection in the mesa portion 60 of the diode portion 80, even when the width of the boundary region 75 in the X axis direction is small, the reverse recovery loss can be suppressed.

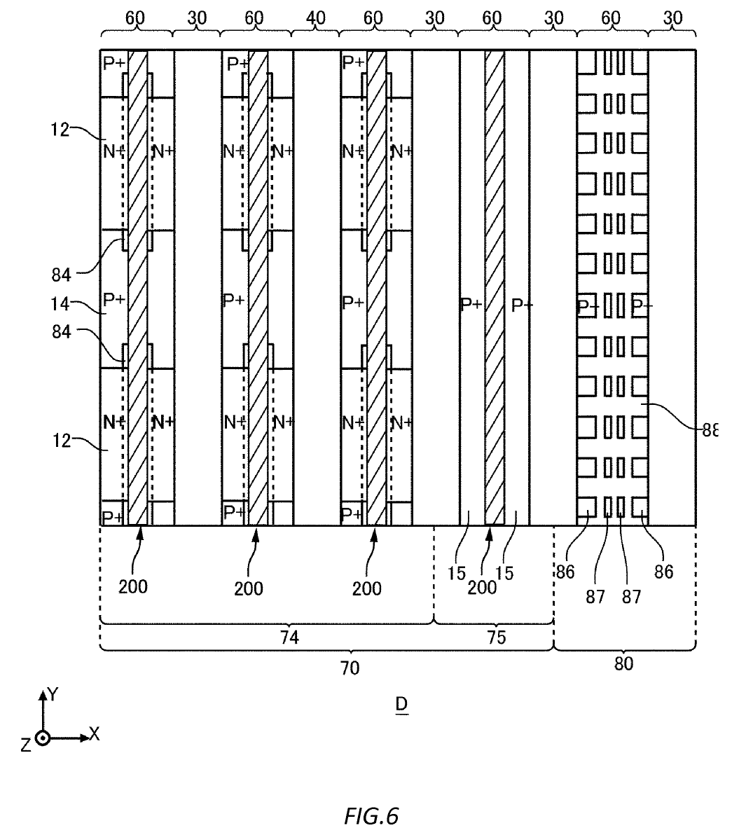

FIG. 6 is another example of the enlarged view of the region D in FIG. 1. FIG. 6 is a top view of the semiconductor substrate 10, and a structure of the mesa portion 60 in the diode portion 80 is different from FIG. 2. Here, a same numeral is given to a common element as in FIG. 2, and its description will be omitted.

In each mesa portion 60 in the diode portion 80 of the present example, a plurality of second conductivity type regions 85 are provided, and each second conductivity type region 85 is spaced apart from an adjacent second conductivity type region 85 in the X axis direction, and spaced apart from an adjacent second conductivity type region 85 in the Y axis direction. In a top view of the semiconductor substrate 10, the first conductivity type region 88 is exposed on the front surface 21 of the semiconductor substrate 10, between adjacent second conductivity type regions 85. That is, in a top view of the semiconductor substrate 10, the second conductivity type region 85 of the present example has a cell structure surrounded by the first conductivity type region 88.

Since the cell structure thus described increases a total peripheral length of the plurality of second conductivity type regions 85, forward voltage Vf of the diode portion 80 can be reduced.

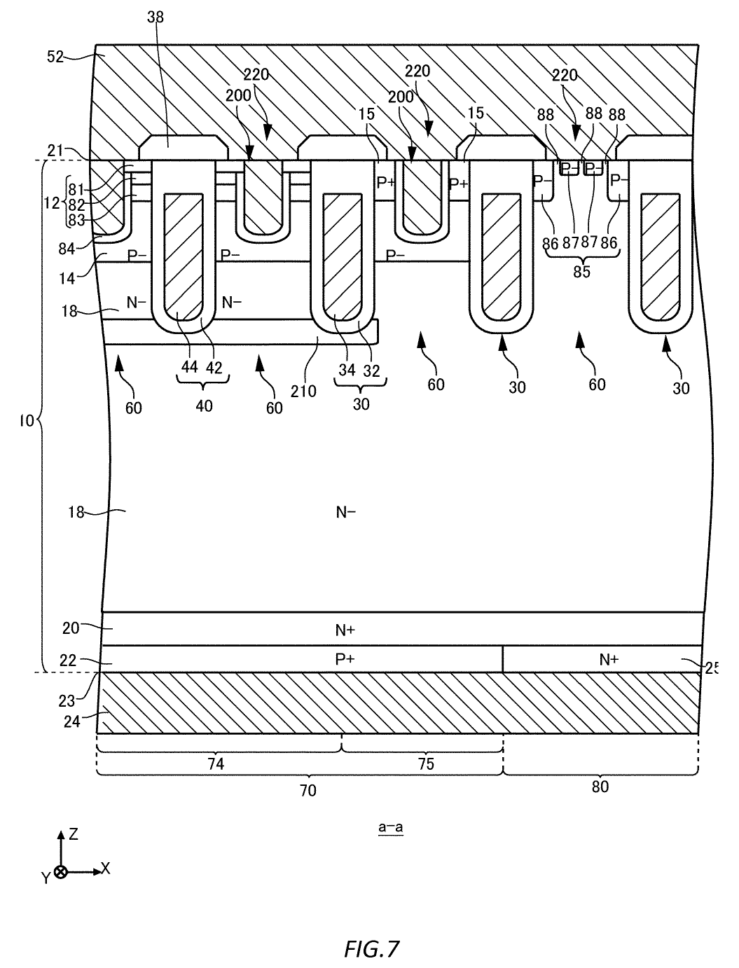

FIG. 7 illustrates another example of the cross section taken along the line a-a in FIG. 2. FIG. 7 is different from FIG. 3 in that in the transistor portion 70, the trench bottom region 210 extends from below one trench portion to below another adjacent trench portion.

In this way, when the trench bottom region 210 extends to span the plurality of trench portions in the X axis direction and extends in the Y axis direction, the trench bottom region 210 have, for example, a mesh-shaped opening in a top view of the semiconductor substrate 10, and the drift regions 18 above and below the trench bottom region 210 may be connected to each other.

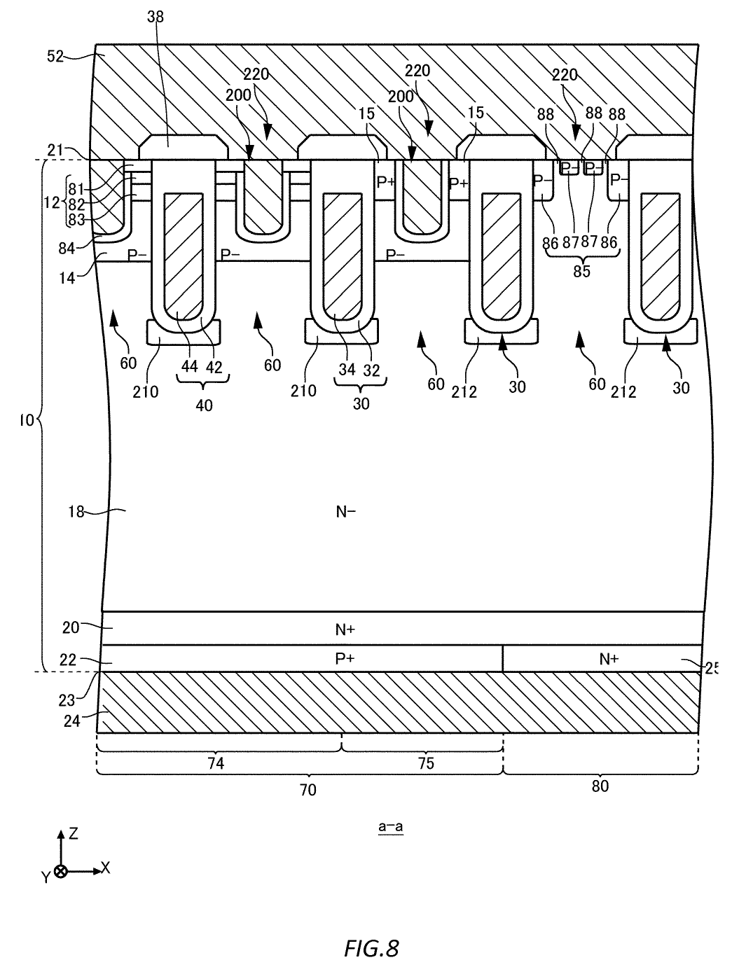

FIG. 8 illustrates another example of the cross section taken along the line a-a in FIG. 2. FIG. 8 is different from FIG. 3 in that a trench bottom region 212 is provided in the diode portion 80, in addition to the trench bottom region 210 provided in the transistor portion 70.

The trench bottom region 212 of the present example is a region of the second conductivity type which is provided below each dummy trench portion 30 in the diode portion 80 and spaced apart from each other. The trench bottom region 212 may have a same structure as the trench bottom region 210.

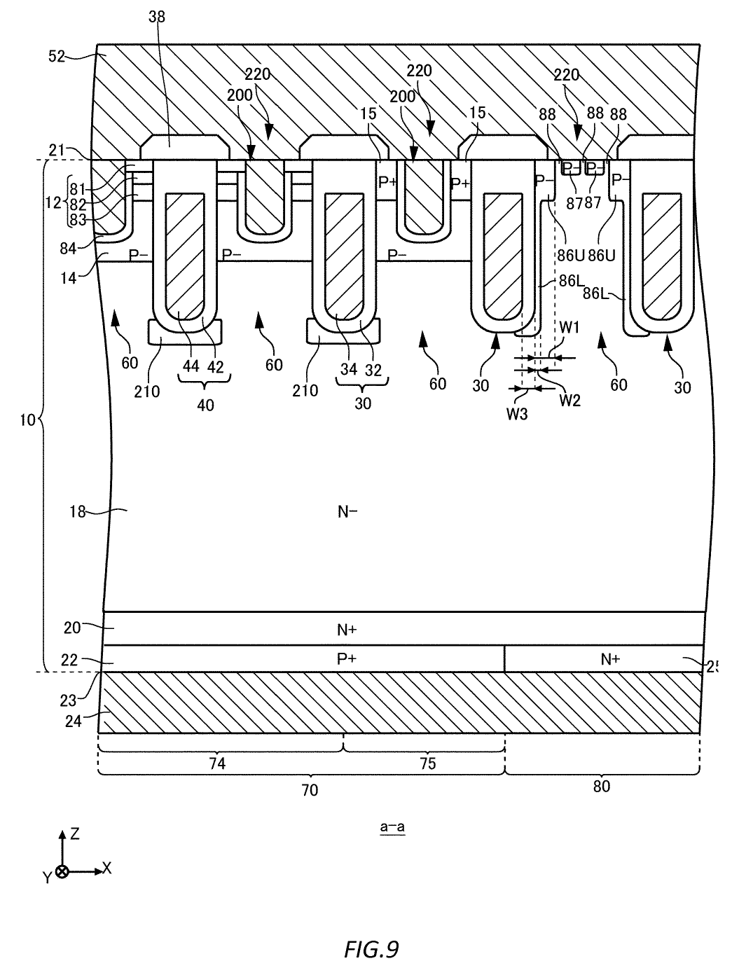

FIG. 9 illustrates another example of the cross section taken along the line a-a in FIG. 2. FIG. 9 is different from FIG. 3 in that the trench sidewall region 86 extends to a lower end of the trench portion. The trench sidewall region 86 of the present example includes a first region 86U which is provided on the front surface 21 of the semiconductor substrate 10 and has a first width W1 in the X axis direction, and a second region 86L which is provided below the first region 86U and has a second width W2 smaller than the first width W1 in the X axis direction. A lower end of the first region 86U of the present example is positioned deeper than the lower end of the front surface region 87. A depth of the lower end of the first region 86U may be greater than or equal to the depth of the lower end of the emitter region 12. The first width W1 may be 0.2 μm or more and 3 μm or less, and the second width W2 may be 0.2 μm or more and 2 μm or less.

The second region 86L may be provided from the sidewall of the dummy trench portion 30 to at least part of a bottom portion of the dummy trench portion 30. That is, the sidewall of the dummy trench portion 30 in the diode portion 80 of the present example is covered with the trench sidewall region 86. This further alleviates the electric field in switching.

The second region 86L of the present example is formed by tilted ion implantation of a P type dopant after trench formation of the dummy trench portion 30. Then, a part of the P type dopant is also implanted in the bottom portion of the trench. Thus, the second region 86L of the trench sidewall region 86 goes from the sidewall to the bottom portion of the dummy trench portion 30 to cover at least part of the bottom portion. In the X axis direction, a width of the second region 86L provided in the bottom portion of the dummy trench portion 30 may be greater than or equal to a sum of the second width W2 of the second region 86L provided on the sidewall of the dummy trench portion 30 and a width W3 of the dummy dielectric film 32. That is, in the X axis direction, the second region 86L provided in the bottom portion of the dummy trench portion 30 extends to a position below a boundary between the dummy conductive portion 34 and the dummy dielectric film 32, or below the dummy conductive portion 34.

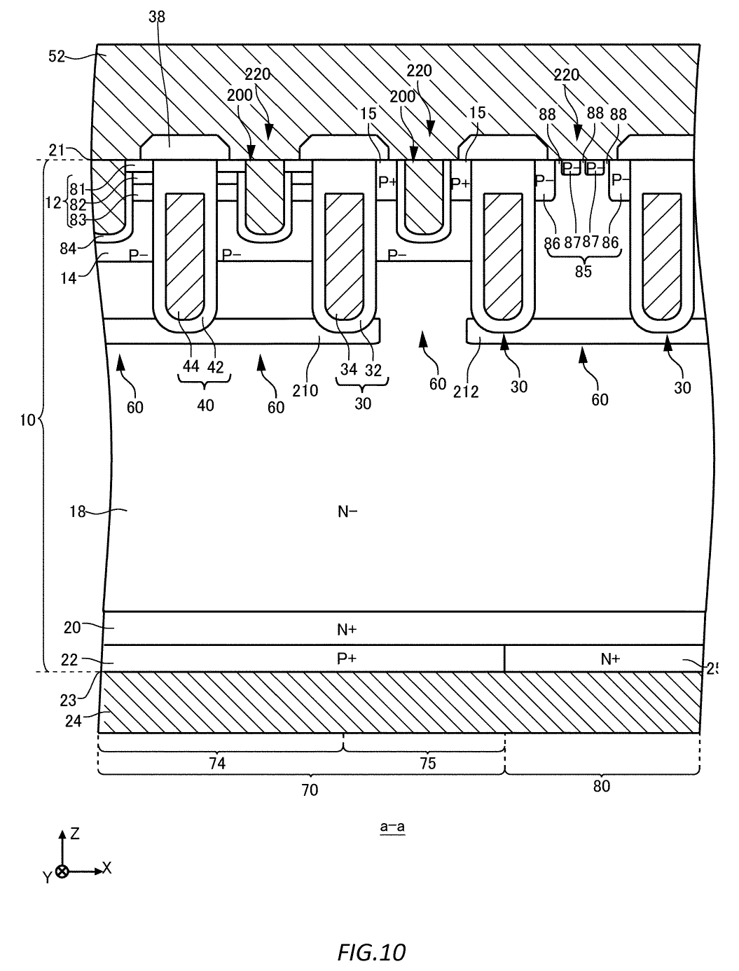

FIG. 10 illustrates another example of the cross section taken along the line a-a in FIG. 2. Although FIG. 10 is in common with FIG. 8 in that the trench bottom region 212 is provided in the diode portion 80, it is different from FIG. 8 in that the trench bottom region 212 extends from below one dummy trench portion to below another adjacent dummy trench portion. The trench bottom region 212 of the present example spans the plurality of dummy trench portions 30 to extend in the X axis direction. The trench bottom region 212 may extend in the Y axis direction.

The boundary region 75 of the present example is not provided with the trench bottom region 210. Therefore, although each of the trench bottom region 210 and the trench bottom region 212 of the present example spans the plurality of trench portions to extend in the X axis direction, they are separate from one another.

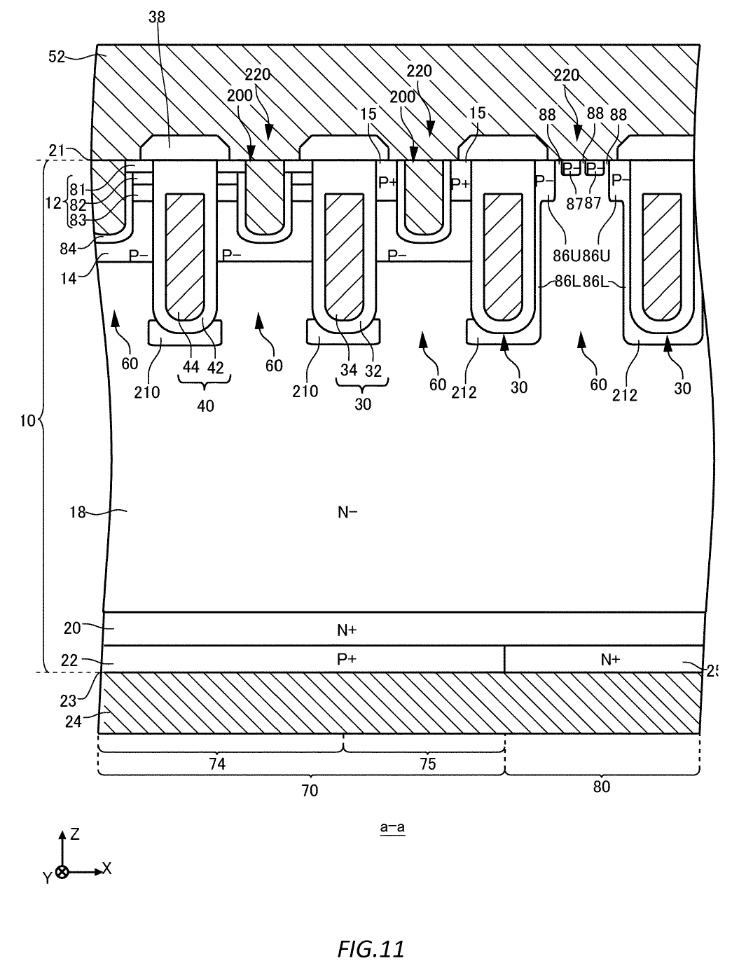

FIG. 11 illustrates another example of the cross section taken along the line a-a in FIG. 2. Although FIG. 11 is in common with FIG. 9 in that the trench sidewall region 86 extends to the lower end of the trench portion, the trench bottom region 212 is also provided in the diode portion 80, as in FIG. 10. The second region 86L of the trench sidewall region 86 of the present example is in contact with the trench bottom region 212. This further alleviates the electric field in switching.

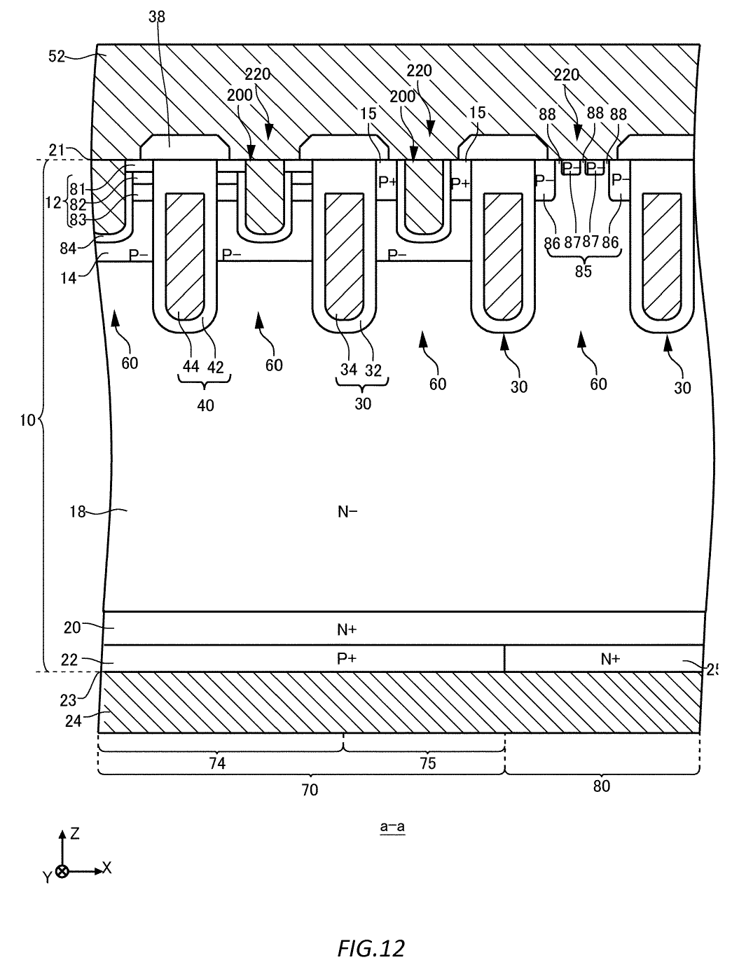

FIG. 12 illustrates another example of the cross section taken along the line a-a in FIG. 2. FIG. 12 is different from FIGS. 3 and 7 in that the trench bottom region 210 is not provided in the transistor portion 70. Furthermore, it is different from FIGS. 8 and 10 in that the trench bottom region 212 is not provided in the diode portion 80, either.

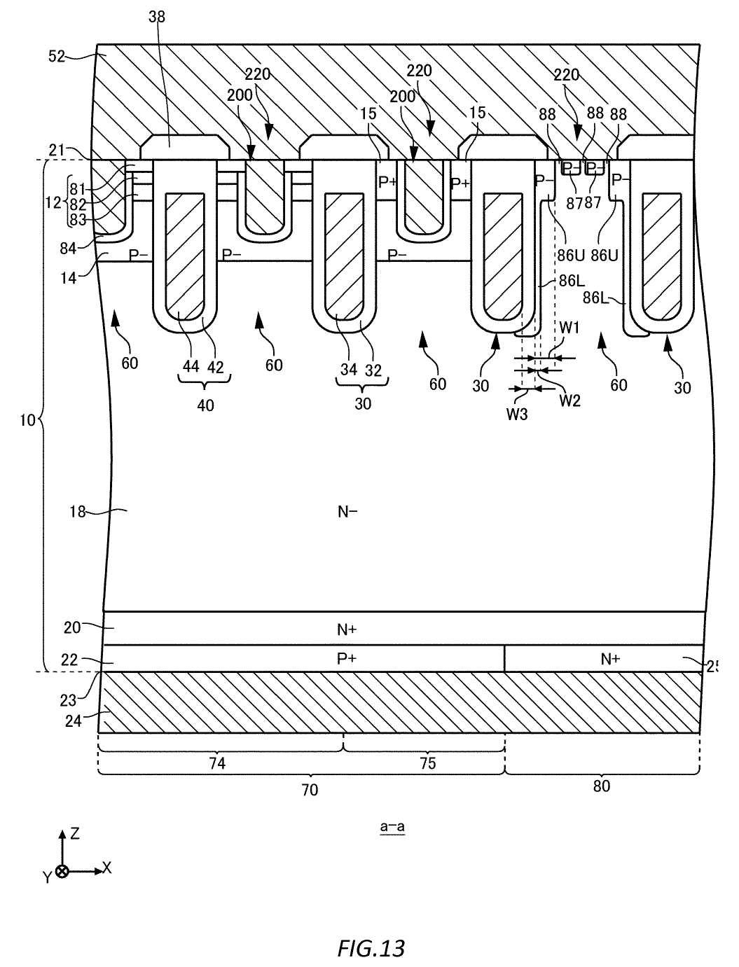

FIG. 13 illustrates another example of the cross section taken along the line a-a in FIG. 2. FIG. 13 is different from FIG. 9 in that the trench bottom region 210 is not provided in the transistor portion 70.

As illustrated in FIGS. 12 and 13, when the trench bottom regions 210 and 212 are not provided, JFET resistance caused by the drift region 18 and the P type region is eliminated. This decreases the ON voltage, and particularly at a high temperature of 150 °C or more, an effect of decreasing the ON voltage becomes greater. Furthermore, a switching loss when turned on can be reduced and a total loss can be reduced.

While the present invention has been described hereinabove by using the embodiment, a technical scope of the present invention is not limited to a scope of the above-described embodiment. It is apparent to persons skilled in the art that various changes or improvements may be made to the embodiment described above. It is also apparent from description of the claims that the embodiment to which such changes or improvements are made can also fall within the technical scope of the present invention.

It should be noted that each process of the operations, procedures, steps, stages, and the like performed by the device, system, program, and method shown in the claims, specification, and drawings may be executed in any order as long as the order is not particularly explicitly indicated by “before”, “prior to”, or the like and as long as an output from a previous process is not used in a later process. Even when the operational flow in the claims, specification, and drawings is described using phrases such as "first", "next", or the like for convenience, it does not necessarily mean that the process must be performed in this order.

### EXPLANATION OF REFERENCES

10: semiconductor substrate; 11: P type outer circumferential well region; 12: emitter region; 14: base region; 15: contact region; 18: drift region; 20: buffer region; 21: front surface; 22: collector region; 23: back surface; 24: collector electrode; 25: cathode region; 30: dummy trench portion; 32: dummy dielectric film; 34: dummy conductive portion; 38: interlayer dielectric film; 40: gate trench portion; 42: gate dielectric film; 44: gate conductive portion; 52: emitter electrode; 60: mesa portion; 70: transistor portion; 74: main region; 75: boundary region; 80: diode portion; 81: first emitter section; 82: second emitter section; 83: third emitter section; 84: trench contact sidewall region; 85: second conductivity type region; 86: trench sidewall region; 87: front surface region; 88: first conductivity type region; 90: edge termination structure portion; 91: peak portion; 92: peak portion; 93: peak portion: 94: valley portion; 95: valley portion; 100: semiconductor device; 130: gate runner; 160: active portion; 161: first end side; 162: second end side; 164: gate pad; 200: trench contact portion; 210: trench bottom region; 212: trench bottom region; 220: contact hole.

What is claimed is:

1. A semiconductor device comprising a transistor portion and a diode portion, comprising:
a drift region of a first conductivity type provided in a semiconductor substrate;
a plurality of trench portions which are provided on a front surface of the semiconductor substrate and extend in a predetermined trench extending direction; and
a front surface electrode portion provided above the semiconductor substrate, wherein
the transistor portion comprises:
a base region of a second conductivity type provided above the drift region;
an emitter region which comprises a first emitter section of the first conductivity type which is in contact with the front surface of the semiconductor substrate and has a higher doping concentration than the drift region, and a second emitter section which is provided below the first emitter section and has a lower doping concentration than the first emitter section;
a trench contact portion which extends from the front surface of the semiconductor substrate in a depth direction of the semiconductor substrate; and
a trench contact sidewall region which is provided on a sidewall of the trench contact portion and provided between the trench contact portion and the second emitter section, and
the diode portion comprises a first conductivity type region of the first conductivity type which is provided above the drift region and in contact with the front surface electrode portion.

2. The semiconductor device according to claim 1, wherein
the diode portion comprises a second conductivity type region of the second conductivity type which is provided above the drift region and in contact with the front surface electrode portion.

3. The semiconductor device according to claim 2, wherein
a doping concentration of the second conductivity type region is higher than or equal to a doping concentration of the base region.

4. The semiconductor device according to claim 2, wherein
in a top view of the semiconductor substrate, the second conductivity type region and the first conductivity type region are formed in a stripe structure, or in a cell structure in which the second conductivity type region is surrounded by the first conductivity type region.

5. The semiconductor device according to claim 2, wherein
the second conductivity type region comprises a trench sidewall region of the second conductivity type which is provided on a sidewall of a dummy trench portion in the diode portion.

6. The semiconductor device according to claim 5, wherein
a depth of a lower end of the trench sidewall region is greater than or equal to a depth of a lower end of the emitter region.

7. The semiconductor device according to claim 5, wherein
the second conductivity type region comprises a front surface region of the second conductivity type which is provided on a front surface of a mesa portion of the semiconductor substrate.

8. The semiconductor device according to claim 7, wherein
a lower end of the trench sidewall region is positioned deeper than a lower end of the front surface region.

9. The semiconductor device according to claim 1, wherein
the second emitter section comprises any of a flat section in which a doping concentration distribution in the depth direction of the semiconductor substrate is flat, a valley portion in which a doping concentration exhibits a local minimum value in the depth direction of the semiconductor substrate, or a peak portion in which a doping concentration exhibits a local maximum value in the depth direction of the semiconductor substrate and is lower than that of a peak portion of the first emitter section.

10. The semiconductor device according to claim 1, wherein
the emitter region comprises a third emitter section which is provided below the second emitter section and has a higher doping concentration than the second emitter section.

11. The semiconductor device according to claim 1, wherein the first conductivity type region is the drift region.

12. The semiconductor device according to claim 1, wherein
the trench contact sidewall region is a region of the second conductivity type provided between the trench contact portion and the second emitter section.

13. The semiconductor device according to claim 1, wherein
the trench contact sidewall region is a trench contact sidewall dielectric film provided on the sidewall of the trench contact portion.

14. The semiconductor device according to claim 1, comprising:
a trench bottom region of the second conductivity type provided below a trench portion in the transistor portion.

15. The semiconductor device according to claim 14, wherein
the trench bottom region extends from below one trench portion to below another adjacent trench portion in the transistor portion.

16. The semiconductor device according to claim 1, comprising
a plurality of trench bottom regions of the second conductivity type each of which is provided below the plurality of trench portions and spaced apart from each other.

17. The semiconductor device according to claim 5, wherein
the trench sidewall region comprises:
a first region which is provided on the front surface of the semiconductor substrate and has a first width in a trench arrangement direction; and
a second region which is provided below the first region and has a second width which is smaller than the first width in the trench arrangement direction.

18. The semiconductor device according to claim 17, wherein
the second region is provided from the sidewall of the dummy trench portion in the diode portion to at least part of a bottom portion of the dummy trench portion.

19. The semiconductor device according to claim 17, comprising:
a trench bottom region of the second conductivity type provided below the dummy trench portion, wherein
the second region is in contact with the trench bottom region.

20. The semiconductor device according to claim 14, wherein
the transistor portion comprises a main region and a boundary region which is provided in closer proximity to the diode portion than the main region; and
the boundary region is not provided with the trench bottom region.
